(19) United States
(12) Patent Application Publication
(10) Pub. No.: US 2006/0240359 A1
(43) Pub. Date: Oct. 26, 2006

(54) PATTERNING PROCESS AND CONTACT STRUCTURE

(76) Inventor: Chih-Hung Liu, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/907,953

(22) Filed: Apr. 22, 2005

(51) Int. Cl. G03F 7/26

(52) U.S. Cl. 430/313; 430/5; 430/311

(57) ABSTRACT

A patterning process is described. A substrate formed with a material layer and a photoresist layer thereon is provided, and then a photomask is provided having a main opaque pattern and a partial-exposure pattern at the periphery of the main opaque pattern thereon. The photoresist layer is exposed through the photomask and then developed to form a patterned photoresist layer that has an inclined sidewall. Thereafter, the material layer is etched using the patterned photoresist layer as a mask, and then the patterned photoresist layer is removed. Because the photomask having a partial-exposure pattern thereon is used in the lithography process, the etched material layer can have an inclined sidewall so that the film deposited subsequently has good uniformity in thickness.

### BACKGROUND OF THE INVENTION

1. Field of the Invention

The present invention relates to a patterning process and a contact structure. More particularly, the present invention relates to a patterning process and a contact structure for liquid crystal display (LCD) applications.

2. Description of the Related Art

Display apparatuses are the interfaces between users and machines. Among various types of display apparatuses, LCD is surely the most popular one. In company with the rapid development of LCD technology, LCD fabricating processes are unceasingly driven in higher yield and more simplification.

FIGS. 1A-1E schematically illustrate a conventional patterning process in LCD fabrication in a cross-sectional view.

Referring to FIG. 1A, a substrate 110 with a material layer 120 and a photoresist layer 130 thereon is provided, and then an exposure process 150 is conducted to expose the photoresist layer 130 using a photomask 140 with an opaque pattern 142 thereon.

Referring to FIG. 1B, the photoresist layer 130 after exposure is developed to form a patterned photoresist layer 132. To make the pattern of the material layer 120 defined later have a less steep sidewall, a heating step 160 is usually conducted to reflow the patterned photoresist layer 132, so that a photoresist pattern 134 having an inclined sidewall 134a is formed, as shown in FIG. 1C.

Referring to FIG. 1C, an etching step 170 is conducted to etch the material layer 120, using the photoresist pattern 134 as a mask, to form a patterned material layer 122 having an inclined sidewall 122a, as shown in FIG. 1D. The photoresist pattern 134 is then removed, as shown in FIG. 1E.

Since the sidewall of the patterned photoresist layer 132 is made inclined with heating/reflow, the patterned material layer 122 can have an inclined sidewall 122a through the etching step 170 that uses the photoresist pattern 134 having an inclined sidewall 134a as a mask. However, because a heating step is additionally conducted in the prior art, the process time is increased, and an extra heater is required.

Moreover, in a contact process of LCD fabrication, the conductive material filled into the contact openings is mostly metal oxide like indium tin oxide (ITO) or indium zinc oxide (IZO). Therefore, the contact resistance of the contact plugs in LCD is higher than that of their metal counterparts.

### SUMMARY OF THE INVENTION

In view of the foregoing, this invention provides a patterning process capable of forming a patterned film having inclined sidewalls without increasing the process time.

This invention further provides a contact structure that has a larger contact area lowering its contact resistance.

A patterning process of this invention is described as follows. A substrate formed with a material layer and a photoresist layer thereon is provided, and then a photomask is provided having a main opaque pattern and a partial-exposure pattern at the periphery of the main opaque pattern thereon. The photoresist layer is exposed through the photomask and then developed to form a patterned photoresist layer that has an inclined sidewall. Thereafter, the material layer is etched using the patterned photoresist layer as a mask, and then the patterned photoresist layer is removed.

The above partial-exposure pattern is a pattern allowing light to pass partially, which may include at least one linear opaque pattern disposed near the main opaque pattern. The material layer may include metal, metal oxide or semiconductor material.

According to a preferred embodiment of this invention, the patterned material layer may have an inclined (non-vertical) sidewall.

This invention provides another patterning process. A substrate formed with a dielectric layer and a photoresist layer thereon is provided, and then a photomask is provided having a transparent pattern and a partial-exposure pattern at the periphery of the transparent pattern thereon. The photoresist layer is exposed through the photomask and then developed to form an opening therein that, which has an inclined sidewall. Thereafter, the dielectric layer is etched using the patterned photoresist layer as a mask to form a contact opening therein, and then the patterned photoresist layer is removed.

According to some preferred embodiments, the partial-exposure pattern may include multiple blockwise opaque patterns. The blockwise opaque patterns may be arranged separately along the boundary of the transparent pattern. Alternatively, the partial-exposure pattern may include at least one ring-like opaque pattern that is disposed along the boundary of the transparent pattern.

In a preferred embodiment, the contact opening can have an inclined sidewall. Moreover, the material of the dielectric layer may be silicon oxide or silicon nitride.

The contact structure of the present invention includes a dielectric layer and a conductive layer. The dielectric layer has a contact opening therein, wherein the upper end of the contact opening has an irregular shape in top view, and the conductive layer covers the contact opening.

According to one preferred embodiment, the contact opening may have an inclined sidewall. The material of the dielectric layer may be silicon oxide or nitride, and the material of the conductive layer may be metal or metal oxide.

Since the photomask used in this invention includes a partial-exposure pattern in company with a main pattern, a patterned photoresist layer can be formed directly with inclined sidewalls to make the later-patterned target layer have inclined sidewalls. Therefore, the thickness uniformity of the subsequently deposited film can be improved to increase the yield. Moreover, since the upper end of the contact structure of this invention has an irregular shape in top view, the contact area of the contact structure can be increased to lower the contact resistance thereof.

It is to be understood that both the foregoing general description and the following detailed description are exemplary, and are intended to provide further explanation of the invention as claimed.

### BRIEF DESCRIPTION OF THE DRAWINGS

FIGS. 1A-1E schematically illustrate a process flow of a conventional patterning process in LCD fabrication in a cross-sectional view.

FIGS. 2A-2E schematically illustrate a process flow of a patterning process according to a preferred embodiment of this invention in a cross-sectional view.

FIGS. 3A and 3B illustrate top views of two examples of photomasks having a main opaque pattern and a partial-exposure pattern thereon according to the preferred embodiment of this invention.

FIGS. 4A-4E schematically illustrate a process flow of a patterning process according to another preferred embodiment of this invention in a cross-sectional view.

FIGS. 5A and 5B illustrate top views of two examples of photomasks for forming a contact opening according to another preferred embodiment of this invention.

FIG. 6A illustrates a perspective view of a contact structure according to another preferred embodiment of this invention, and FIG. 6B illustrates a cross-sectional view of the contact structure in FIG. 6A along line I-I′.

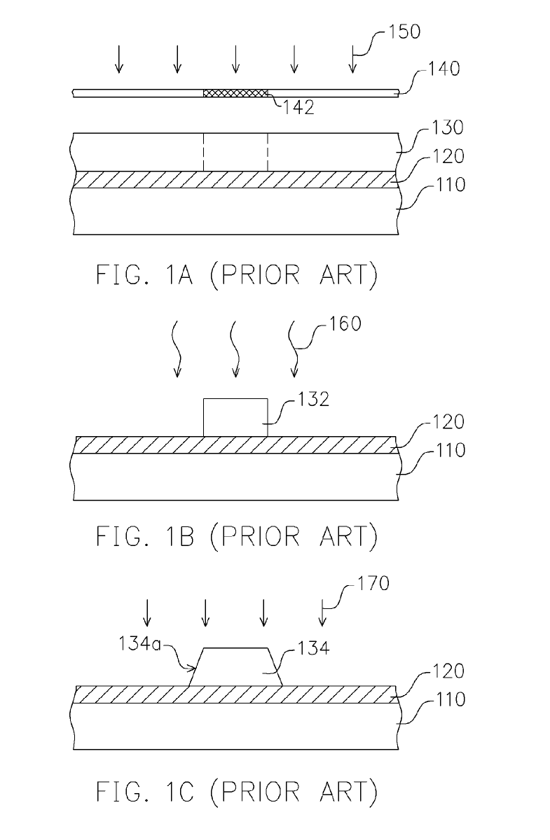

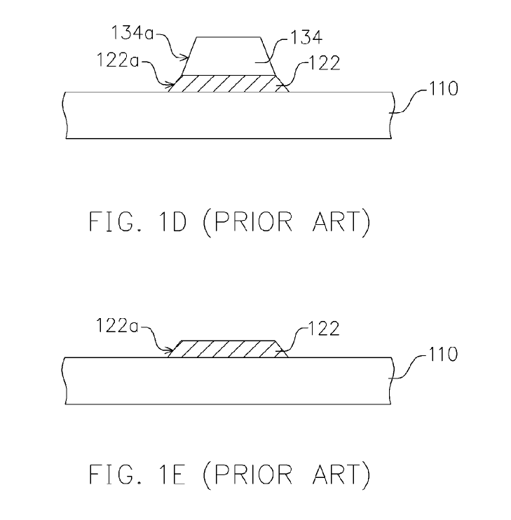

### DESCRIPTION OF THE PREFERRED EMBODIMENTS

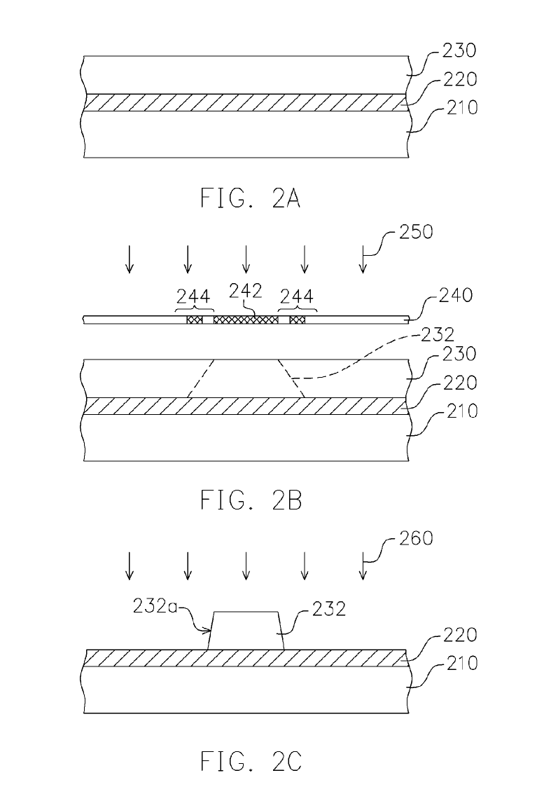

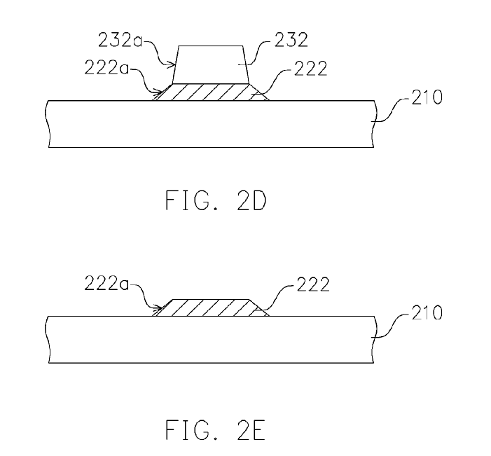

FIGS. 2A-2E schematically illustrate a process flow of a patterning process according to a preferred embodiment of this invention in a cross-sectional view.

Referring to FIG. 2A, a substrate 210 formed with a material layer 220 and a photoresist layer 230 thereon is provided. In the preferred embodiment, the substrate 210 may be a glass substrate, and the material of the material layer 220 is, for example, metal, metal oxide or semiconductor material. In cases where this invention is applied to LCD fabrication, the material layer 220 may be a film predetermined to pattern into gate electrodes, source/drain electrodes or channel layers of thin-film transistors (TFT), or pixel electrodes.

Referring to FIG. 2B, a photomask 240 is provided, having a main opaque pattern 242 and a partial-exposure pattern 244 at the periphery of the main opaque pattern 242 thereon. An exposure step 250 is then performed to expose the photoresist layer 230 through the photomask 240.

Referring to FIG. 2C, the photoresist layer 230 after exposure is developed to form a patterned photoresist layer 232, which has an inclines sidewall 232a. An etching step 260 is conducted to etch the material layer 220, using the patterned photoresist layer 232 as a mask, to form a patterned material layer 222, as shown in FIG. 2D. The patterned photoresist layer 232 is then removed, as shown in FIG. 2E.

It is noted that the partial-exposure pattern 244 can reduce the exposure dosage at the periphery of the main opaque pattern 242 in the exposure step 250, so that the corresponding portions of the photoresist layer 230 is partially exposed to form an inclined sidewall 232a of the photoresist pattern 232.

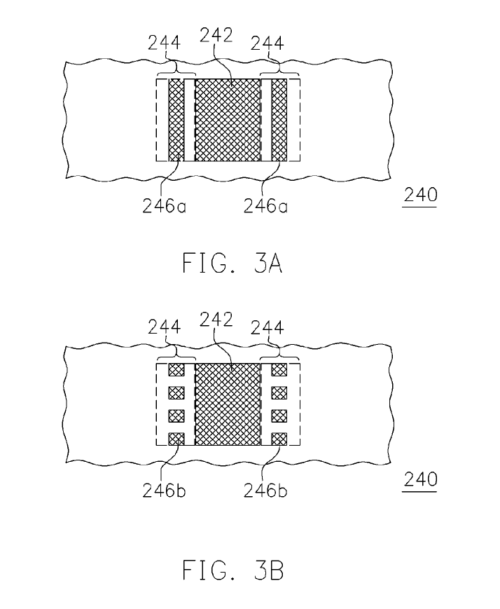

According to a preferred embodiment, the partial-exposure pattern 244 may include at least one linear opaque pattern. FIGS. 3A and 3B illustrate top views of two examples of such photomasks according to the preferred embodiment.

Referring to FIG. 3A, the photomask 240 has a main opaque pattern 242 and two partial-exposure patterns 244 beside the main opaque pattern 242. Each partial-exposure pattern 244 may include one linear opaque pattern 246a near the main opaque pattern 242, through which the exposure dosage beside the main opaque pattern 242 is reduced partially exposing the corresponding portions of the photoresist layer 230 to form an inclined sidewall 232a of the photoresist pattern 232 (FIG. 2B). Alternatively, each partial-exposure pattern 244 is not restricted to include only one linear opaque pattern 246a, but may include multiple such linear opaque patterns 246a.

Referring to FIG. 3B, each partial-exposure pattern 244 on the photomask 240 may alternatively includes multiple blockwise opaque patterns 246b, which are arranged along one boundary of the main opaque pattern 242 to control the exposure dosage and thereby cause partial exposure at the corresponding portion of the photoresist layer 230. It is noted that the opaque patterns in the partial-exposure patterns 244 can have any other shape if only partial exposure can be caused at the periphery of the main opaque pattern 242.

Referring to FIG. 2E, in the preferred embodiment, the patterned photoresist layer 232 having an inclined sidewall is used as an etching mask to etch the material layer 220 to form a patterned material layer 222, which also has an inclined sidewall because of the inclined sidewall of the photoresist pattern 232. Therefore, when a subsequent film is being deposited on the patterned material layer 222 with, for example, sputtering, the film can be deposited more smoothly to have better uniformity in thickness. As compared with the prior-art cases where a film is deposited on a patterned material layer (132) having a vertical sidewall, this invention is capable of preventing thinning of the deposited film on the sidewall of the patterned material layer (132) or poor thickness uniformity over the whole film.

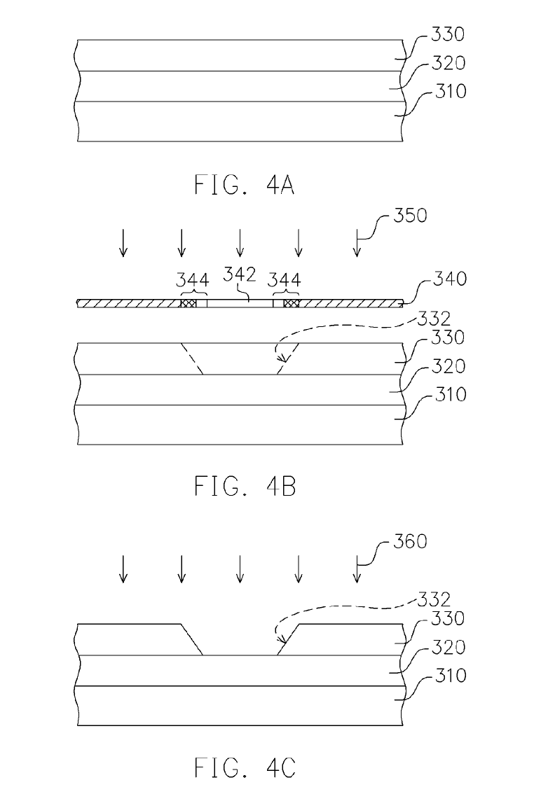

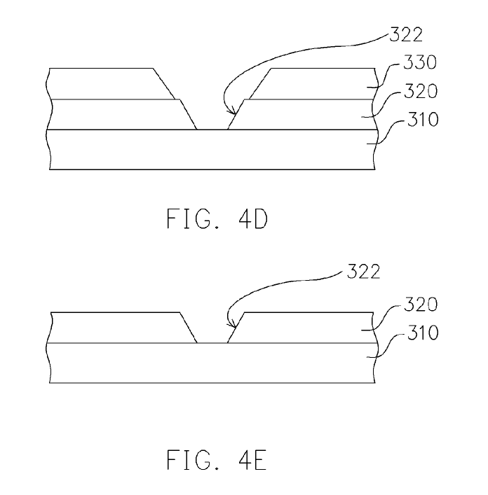

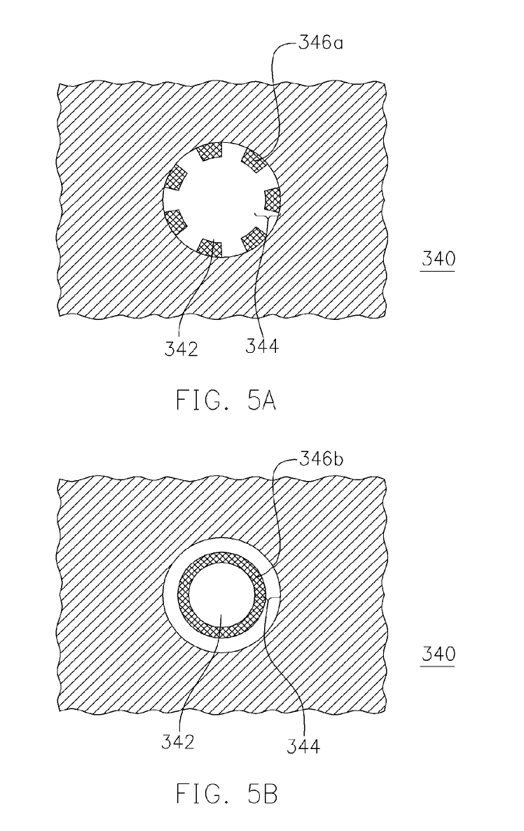

FIGS. 4A-4E schematically illustrate a process flow of a patterning process according to another preferred embodiment of this invention in a cross-sectional view. The patterning process is suitably used to define a contact opening.

Referring to FIG. 4A, a substrate 310 formed with a dielectric layer 320 and a photoresist layer 330 thereon is provided. In some embodiments, the material of the dielectric layer 320 is, for example, silicon oxide, silicon nitride or any other suitable dielectric material in the prior art.

Referring to FIG. 4B, a photomask 340 is provided, having a transparent pattern 342 and a partial-exposure pattern 344 at the periphery of the transparent pattern 342 thereon. An exposure step 350 is then conducted to expose the photoresist layer 330 through the photomask 340.

Referring to FIG. 4C, the photoresist layer 330 is developed to form an opening 332 therein, wherein the opening 332 has an inclined sidewall due to partial exposure. An etching step 360 is then conducted, using the photoresist layer 330 having the opening 332 therein as a mask, to etch the dielectric layer 320 to form a contact opening 322 therein, as shown in FIG. 4D. In a preferred embodiment, the contact opening 322 also has an inclined sidewall because of the inclined sidewall of the opening 332 in the photoresist layer 330. The photoresist layer 330 is then removed, as shown in FIG. 4E. Thereafter, a conductive layer (not shown) is formed covering the contact opening 322 to constitute a contact structure.

It is noted that the partial-exposure pattern 344 can reduce the exposure dosage at the periphery of the transparent pattern 342 in the exposure step 350, so that the photoresist layer 330 at the periphery of the opening 332 is partially exposed to form an inclined sidewall of the opening 332.

FIGS. 5A and 5B illustrate top views of two examples of photomasks for forming a contact opening according to another preferred embodiment of this invention.

Referring to FIG. 5A, the photomask 340 has a hole-like transparent pattern 342 and a partial-exposure pattern 344 thereon. The partial-exposure pattern 344 may include multiple blockwise opaque patterns 346a, while the blockwise opaque patterns 346a may be arranged separately along the boundary of the transparent pattern 342, such that partial exposure is caused at the periphery of the opening 332 (FIG. 4B) in the photoresist layer 330.

Referring to FIG. 5B, the partial-exposure pattern 344 may alternatively include a ring-like opaque pattern 346b, while the ring-like opaque pattern 346b may be disposed along the boundary of the transparent pattern 342, such that partial exposure is caused at the periphery of the opening 332 (FIG. 4B) in the photoresist layer 330.

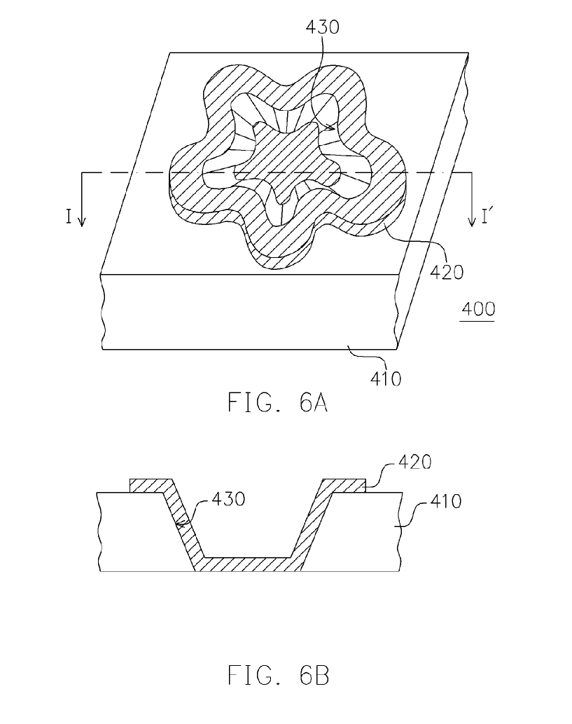

Moreover, when the contact opening 322 is defined with the photomask 340 of FIG. 5A, the upper end of the contact opening 322 can have an irregular shape in top view. FIG. 6A illustrates a perspective view of such a contact structure according to another preferred embodiment of this invention, and FIG. 6B illustrates a cross-sectional view of the contact structure in FIG. 6A along line I-I′.

Referring to FIGS. 6A and 6B, the contact structure 400 includes a dielectric layer 410 and a conductive layer 420. The dielectric layer 410 has a contact opening 430 therein, wherein the upper end of the contact opening 430 has an irregular shape in top view, and the conductive layer 420 covers the contact opening 430.

In addition, the material of the dielectric layer 410 may be silicon oxide, silicon nitride or any other suitable dielectric material in the prior art, and the material of the conductive layer 420 may be metal or metal oxide.

As shown in FIG. 6B, since the irregularly shaped contact opening 430 has an inclined sidewall, the conductive layer 420 can be deposited uniformly in the contact opening 430. Moreover, since the upper end of the contact opening 430 has an irregular shape in top view, the contact area of the contact structure 400 can be increased to lower the contact resistance thereof.

In summary, the patterning process of this invention utilizes a lithographic technique with partial exposure design to directly form a patterned film having inclined sidewalls without reflowing the photoresist pattern by heating, so that the fabricating process can be simplified. Moreover, since the partial exposure design of this invention can make a film pattern or contact opening have an inclined sidewall, the later deposited film is more uniform in thickness so that the process yield can be increased. Furthermore, since the upper end of the contact structure of this invention has an irregular shape in top view, the contact area of the contact structure can be increased to lower the contact resistance thereof.

What is claimed is:

1. A patterning process, comprising:
providing a substrate having a material layer and a photoresist layer thereon;
providing a photomask having a main opaque pattern and a partial-exposure pattern at periphery of the main opaque pattern thereon;
exposing the photoresist layer through the photomask;
developing the photoresist layer to form a patterned photoresist layer that has an inclined sidewall;
etching the material layer with the patterned photoresist layer as a mask to form a patterned material layer; and
removing the patterned photoresist layer.

2. The patterning process of claim 1, wherein the partial-exposure pattern comprises at least one linear opaque pattern near the main opaque pattern.

3. The patterning process of claim 1, wherein the material layer comprises metal, metal oxide or semiconductor material.

4. The patterning process of claim 1, wherein the patterned material layer also has an inclined sidewall.

5. A patterning process, comprising:
providing a substrate having a dielectric layer and a photoresist layer thereon;
providing a photomask having a transparent pattern and a partial-exposure pattern at periphery of the transparent pattern thereon;
exposing the photoresist layer through the photomask;
developing the photoresist layer to form an opening in the photoresist layer, wherein the opening has an inclined sidewall;
etching the dielectric layer with the photoresist layer as a mask to form a contact opening in the dielectric layer; and
removing the photoresist layer.

6. The patterning process of claim 5, wherein the partial-exposure pattern comprises a plurality of blockwise opaque patterns.

7. The patterning process of claim 6, wherein the blockwise opaque patterns are disposed separately along a boundary of the transparent pattern.

8. The patterning process of claim 5, wherein the partial-exposure pattern comprises at least one ring-like opaque pattern.

9. The patterning process of claim 8, wherein the ring-like opaque pattern is disposed along a boundary of the transparent pattern.

10. The patterning process of claim 5, wherein the contact opening also has an inclined sidewall.

11. The patterning process of claim 5, wherein the dielectric layer comprises silicon oxide or silicon nitride.

12. A contact structure, comprising a dielectric layer having a contact opening therein and a conductive layer covering the contact opening, wherein an upper end of the contact opening has an irregular shape in top view.

13. The contact structure of claim 12, wherein the contact opening has an inclined sidewall.

14. The contact structure of claim 12, wherein the dielectric layer comprises silicon oxide or silicon nitride.

15. The contact structure of claim 12, wherein the conductive layer comprises metal or metal oxide.
